(19) United States
(12) Patent Application Publication
(10) Pub. No.: US 2007/0254482 A1
(43) Pub. Date: Nov. 1, 2007

(54) Method and system for manufacturing a semiconductor device

(76) Inventors: Kenji Kawabata, Yokohama-Shi (JP); Junji Sugamoto, Oita-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/790,388

(22) Filed: Apr. 25, 2007

(30) Foreign Application Priority Data
Apr. 26, 2006 (JP) 2006-122540

(51) Int. Cl. H01L 21/66; H01L 23/58; H01L 21/44

(52) U.S. Cl. 438/688; 438/14; 257/48

(57) ABSTRACT

A method for manufacturing a semiconductor device has measuring a finished state of a wafer in a completed process, estimating an in-surface tendency of the wafer based on a result of the measuring, estimating a surface characteristic of the wafer based on the estimated in-surface tendency, setting a process condition of a uncompleted process based on the estimated surface characteristic and controlling the uncompleted process based on the set process condition.

### CROSS-REFERENCE TO RELATED APPLICATION

This application is based upon and claims the benefit of priority from the prior Japanese Patent Application No. 2006-122540, filed on Apr. 26, 2006; the entire contents of which are incorporated herein by reference.

### BACKGROUND OF THE INVENTION

1. Field of the Invention

The present invention relates to a method of a manufacturing semiconductor device and manufacturing system and, more particularly, to a control of a semiconductor device manufacturing process.

2. Related Art

In a conventional semiconductor device manufacturing method, the yield thereof has been increased by improving uniformity of a surface of a wafer in each manufacturing process. Recently, as the semiconductor device is miniaturized and a size of the wafer is increased, it is difficult to improve the uniformity of the surface of the wafer in each manufacturing processes. Therefore, there is a limitation to the increasing of the yield through the improving of the uniformity of the surface of the wafer.

In order to solve the aforementioned problem, Japanese Patent Application Laid-Open No. 7-302826 (Patent Document 1) describes a product manufacturing method capable of increasing the yield by optimizing an uncompleted process according to a simulation result of the uncompleted process that is obtained by simulating a result of the uncompleted process based on a result of a completed process.

In addition, Japanese Patent Publication No. 6-16475 (Patent Document 2) describes an electronic circuit device manufacturing method of simulating a result of an uncompleted process based on a measurement result and history information of a completed process and selecting an optimal process according to a simulation result.

However, in the Patent Documents 1 and 2, a surface topography of the wafer cannot be considered. Therefore, in a case where a finished state tendency in a surface of a wafer (hereinafter simply described as in-surface tendency) is different among the processes, the yield in terms of the entire surface of the wafer cannot be increased.

### SUMMARY OF THE INVENTION

According to a first aspect of the present invention, there is provided a semiconductor device manufacturing method, comprising: measuring a finished state of a wafer in a completed process; estimating an in-surface tendency of the wafer based on a result of the measuring; estimating a surface characteristic of the wafer based on the estimated in-surface tendency; setting a process condition of a uncompleted process based on the estimated surface characteristic; and controlling the uncompleted process based on the set process condition.

According to a second aspect of the present invention, there is provided a semiconductor device manufacturing system comprising: an in-surface tendency estimation unit which measures a finished state of a wafer in a completed process and estimates an in-surface tendency of the wafer based on a result of the measuring; a characteristic estimation unit which estimates a surface characteristic of the wafer based on the estimated in-surface tendency; a process condition setting unit which sets a process condition of a uncompleted process based on the estimated surface characteristic; and a controller which controls the uncompleted process based on the set process condition.

### BRIEF DESCRIPTION OF THE DRAWINGS

FIG. 1 is a block diagram showing an example of a system for manufacturing a semiconductor device according to the present invention;

FIG. 2 is a flowchart showing an example of a manufacturing process of a semiconductor device according to the present invention;

FIG. 3 is a cross-sectional view of a device showing an example of a finished state of a film forming process according to the present invention;

FIG. 4 is a cross-sectional view of a device showing an example of a finished state of a CMP process according to the present invention;

FIG. 5 is a cross-sectional view of a device showing an example of a finished state of a isolation region forming process following a CMP process according to the present invention;

FIG. 6 is a cross-sectional view of a device showing an example of a finished state of an etching process according to the present invention;

FIG. 7 is a flowchart showing an example of an optimization operation performed by a controller 101 according to the present invention;

FIG. 8 is a conceptual view showing an example of an in-surface tendency estimation operation performed by an in-surface tendency estimation unit 102 according to the present invention;

FIG. 9 is a flowchart showing an example of an optimization operation performed by a controller 101 according to the present invention;

FIG. 10 is a flowchart showing an example of a particle risk estimation operation performed by an in-surface tendency estimation unit 102 according to the present invention;

FIG. 11 is a view for explaining an example of a partitioned data produced by a partitioned data acquisition unit 105 according to the present invention;

FIG. 12 is a view for explaining an example of a data associated with particles;

FIG. 13 is a flowchart showing a selection operation performed by a selection unit 106 according to the present invention; and

FIG. 14 is a view for explaining an example of a verification result showing an effect of a third embodiment.

### DETAILED DESCRIPTION Of THE INVENTION

Hereinafter, embodiments of the present invention are described with reference to the accompanying drawings. In the embodiments, methods and systems for implementing a technical spirit of the present invention are described. Therefore, the present invention is not limited to the embodiments described below.

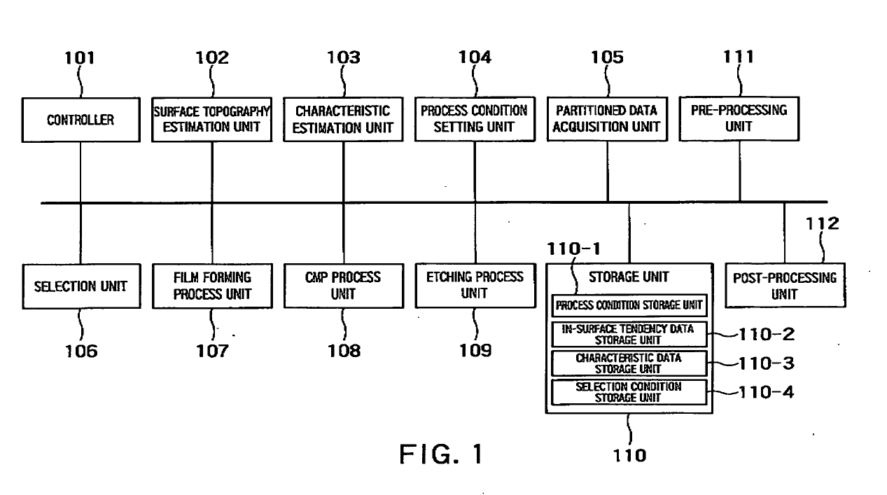

FIG. 1 shows an example of system for manufacturing a semiconductor device according to the present invention.

The semiconductor device manufacturing system includes a controller 101, an in-surface tendency estimation unit 102, a characteristic estimation unit 103, a process condition setting unit 104, a partitioned data acquisition unit 105, a selection unit 106, a film forming process unit 107, a chemical mechanical polishing (CMP) process unit 108, an etching process unit 109, a storage unit 110, a pre-processing unit 111, and a post-processing unit 112. However, the components of the manufacturing system according to the present invention are not limited to the aforementioned components.

The storage unit 110 includes; a process condition storage part 110-1 which stores process conditions (process-unit parameters) used for process units; an in-surface tendency data storage part 110-2 which stores a estimation result obtained by the in-surface tendency estimation unit 102; a characteristic data storage part 110-3 which stores a estimation result obtained by the characteristic estimation unit 103; and a selection condition storage part 110-4 which stores a selection condition used for a selection operation. In addition, the storage unit 110 may store other data, for example, a control program for controlling the process units.

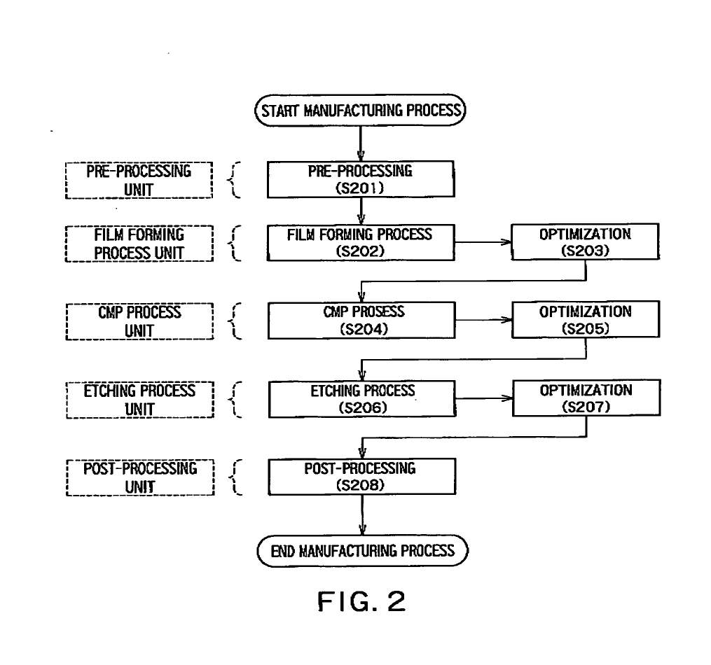

FIG. 2 shows an example of a semiconductor device manufacturing process according to the present invention.

Firstly, the pre-processing unit 111 performs a pre-processing S201 including a process of cleaning a silicon wafer. Next, film forming process unit 107 performs a film forming process S202 to form a silicon nitride film (SiN film). Next, the controller 101 performs optimization S203 for the process conditions after the CMP process. Next, the CMP process unit 108 performs a CMP process S204 based on the optimized process conditions to polish the wafer. Next, the controller 101 performs optimization S205 for the process conditions after the etching process. Next, the etching process unit 109 performs an etching process S206 based on the optimized process conditions to form elements. Next, the controller 101 performs optimization S207 for the process conditions of the post-processing. Next, the post-processing unit 112 performs a post-processing S208 including a resist removing process based on the optimized process condition. When the manufacturing processes including the aforementioned processes are completed, the semiconductor device is formed on surface of the wafer.

The controller 101 controls the process units including the pre-processing unit 111, the film forming process unit 107, the CMP process unit 108, the etching process unit 109, and the post-processing unit 112 based on the process conditions stored in the process condition storage part 110-1. The process units perform the corresponding processes under the control of the controller 101.

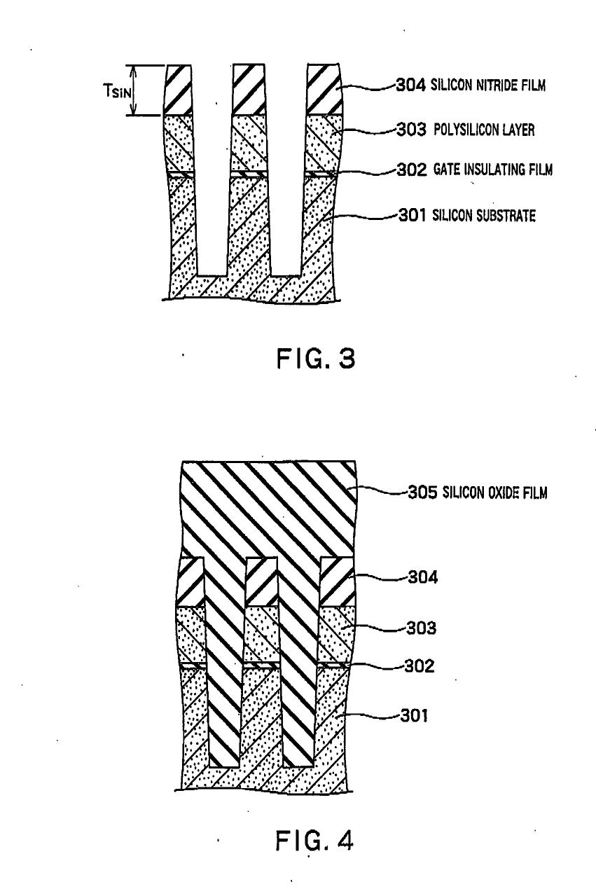

FIG. 3 shows a finished state obtained by performing the film forming process S202 and an isolation region forming process.

A gate insulating film 302 and a polysilicon layer 303 are formed on a silicon (Si) substrate 301. Subsequently, a silicon nitride film (SiN film) 304 is deposited by using a chemical vapor deposition (CVD) method, and trenches are formed by using a photolithography method and an etching method. Here, a thickness T_{SiN} of the SiN film 304 is selected as a finished data of the film forming process S202.

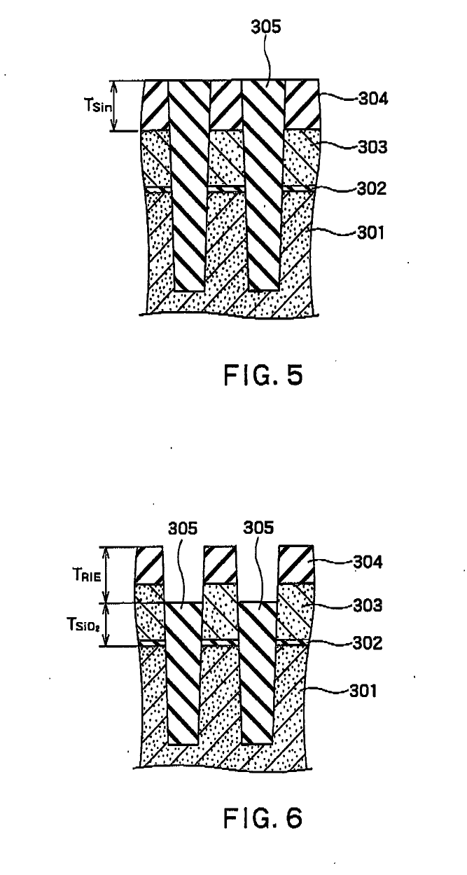

FIG. 4 is a finished state obtained by depositing a silicon oxide film (SiO₂ film) 305 on the isolation region. FIG. 5 shows a finished state of the CMP process S204.

As shown in FIG. 5, the SiO₂ film 305 is flattened by using a CMP method using the SiN film 304 as a stopper film. Here, a thickness T_{SiN} of the SiN film 304 after the flattening is selected as a finished data of the CMP process S204.

FIG. 6 shows a finished state of the etching process S206.

As shown in FIG. 6, the SiO₂ film 305 is selectively removed by using a reactive ion etching (RIE) method. Here, a thickness T_{RIE} etched per unit time of the SiO₂ film 305 is selected as a finished data of the etching process S206. In addition, a thickness T_{SiO2} of a remaining film of the SiO₂ film 305 from a surface of the Si substrate 301 is selected a finished data obtained from the film forming process S202, the CMP process S204, and the etching process S206.

Although the processes S201 to S208 are described in the following embodiments, various other sequences of processes may be similarly performed. In the following embodiments, the processes S201 to S204 are assumed to be complete processes, and the processes S205 to S208 are assumed to be uncompleted processes.

### First Embodiment

Now, a semiconductor device manufacturing method and system according to a first embodiment of the present invention are described.

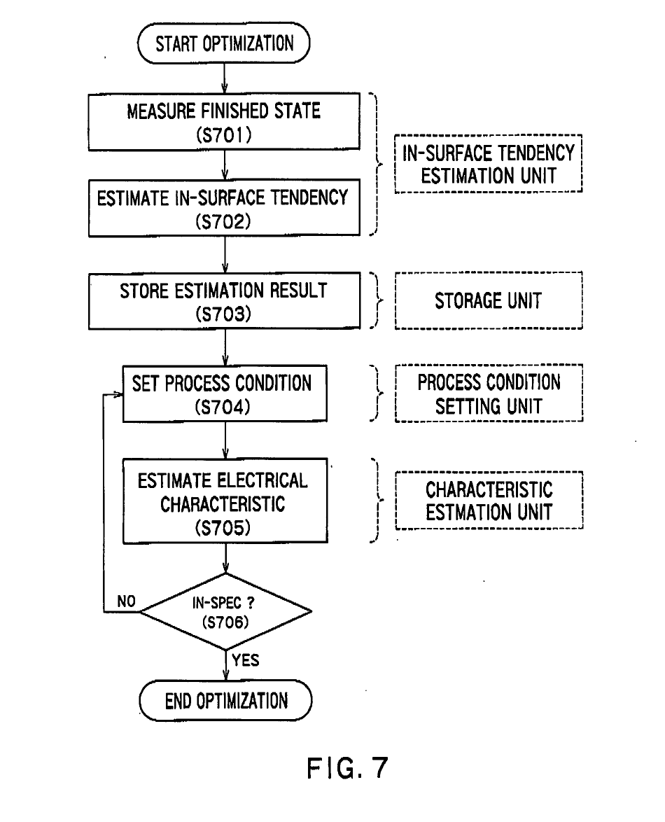

FIG. 7 shows an example of processes performed by the controller 101 in the optimization S205 shown in FIG. 2. The storage unit 110 stores information (for example, an in-surface tendency data and process conditions) which is previously obtained by performing the semiconductor device manufacturing method according to the present invention.

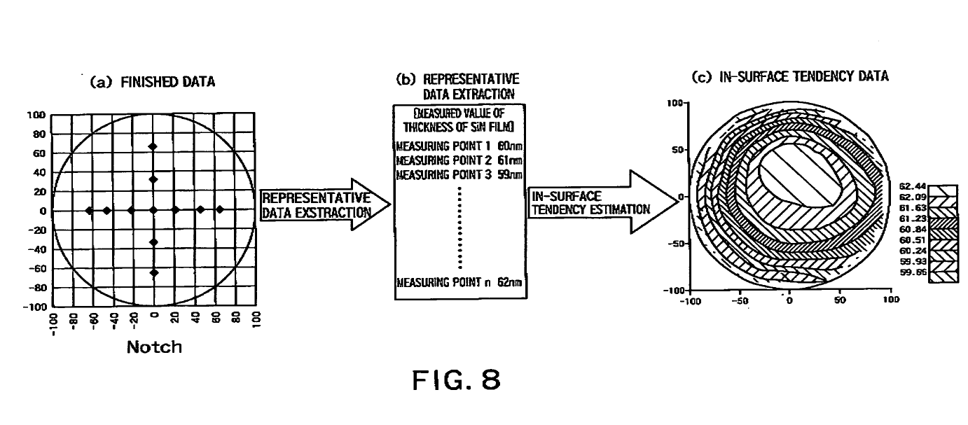

Firstly, in the in-surface tendency estimation unit 102, a finished data T_{SiN} (see FIG. 8A) after the CMP process shown in FIG. 5 is measured (S701), and a representative data (see FIG. 8B) is extracted from the measurement result, and an in-surface tendency data (see FIG. 8C) is estimated based on the extracted result (S702). The in-surface tendency estimation unit 102 estimates the in-surface tendency data based on the extracted result (see FIG. 8B) on which a previously stored in-surface tendency data stored in the storage unit 110 is reflected.

Next, the in-surface tendency data (see FIG. 8C) is stored in the in-surface tendency data storage part 110-2 (S703). Next, in the process condition setting unit 104, a process condition of the etching process (S206) is set (S704). As an example, the process condition setting unit 104 may modify a processing time that is one of the process conditions of the etching process so that the finished data T_{SiO2} of the etching process can be the thickness that satisfy a final electrical characteristic. As an alternative example, the process condition setting unit 104 may modify a temperature parameter that is one of the process conditions of the etching process so that the finished data T_{SiO2} of the etching process of the etching process unit 109 can be uniform over the surface of the wafer. The set process condition is stored in the process condition storage part 110-1. Next, the process condition stored in the process condition storage part 110-1 and the in-surface tendency data (see FIG. 8C) are applied to the characteristic estimation unit 103, so that a characteristic (for example, an electrical characteristic) of the completed manufacturing process is estimated (S705).

Next, it is determined whether or not the estimated electrical characteristic stratifies a specification over the entire surface of the wafer (in-spec). If the estimated electrical characteristic is determined not to be in the in-spec state (that is, in the out-of-spec state) (No in S706), the process condition setting unit 104 repeats the process condition setting (S704) until the electrical characteristic satisfies predetermined specification (it is in the in-spec state) over the entire surface of the wafer. If the estimated electrical characteristic is determined to be in the in-spec state (Yes in S706), the optimization is ended, and the set process condition is stored in the process condition storage part 110-1. Subsequently, the next process, that is, the etching process (S206) is performed.

As an example of the standard for determining the in-spec state, the following condition expressed by Equation 1 can be used. Here, E, T, and U denote the estimation result (an estimated value of electrical characteristic) of the characteristic estimation unit 103, a target value, and an allowable specification range (an allowable value).
T−U≦E≦T+U [Equation 1]

Namely, the controller 101 controls the process condition setting unit 104 so that the estimated value E of electrical characteristic E can be close to the target value T (or be in the range of the allowable value U). When the estimated value E of electrical characteristic E is close to the target value T, the entire surface of the wafer can be determined to be in the in-spec state (Yes in S706). Accordingly, the yield in term of the entire surface of the wafer can be increased.

Although the first embodiment is applied to the optimization S205 performed before the etching process, it can be applied to the optimization S203 performed before the CMP process and the optimization S207 performed after the etching process.

In addition, in the determination S706 of the in-spec state, the best-yield process condition may be selected and set among a plurality of process conditions (for example, the process condition of the film forming process, the process condition of the CMP process, and the process condition of the etching process) and combinations of the process conditions. In addition, in the setting S704 of the process condition, the process conditions of the completed processes, that is, the film forming process S202 and the CMP process S204 may be set, so that the yield of a new lot manufacturing process can be increased.

According to the semiconductor device manufacturing method and system of the first embodiment, the process condition of the uncompleted process is set based on the in-surface tendency of the wafer, so that the yield in terms of the entire surface of the wafer can be increased.

### Second Embodiment

Now, a second embodiment of a semiconductor device manufacturing method and system of capable of further increasing the yield in comparison with the first embodiment is described. In description of the second embodiment, the same construction and operations as the first embodiment are omitted.

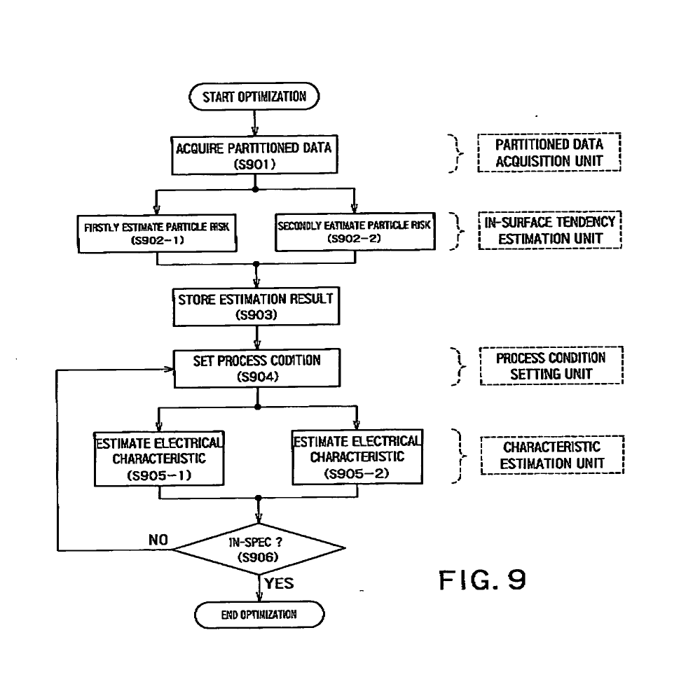

FIG. 9 shows an example of processes performed by the controller 101 in the optimizations S203, 205, and 207 according to the second embodiment.

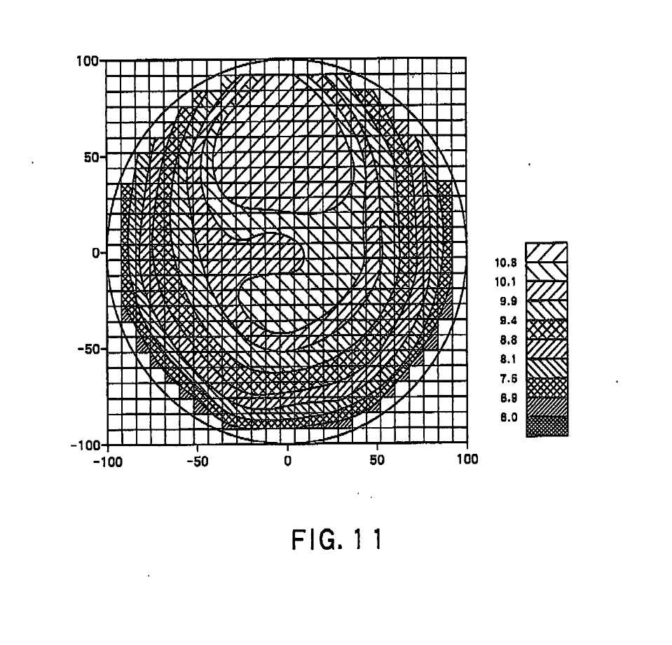

Firstly, in the partitioned data acquisition unit 105, partitioned data of predetermined partitioned regions (for example, meshes of a mesh shape shown in FIG. 11) of the surface of the wafer are acquired (S901). Next, in the in-surface tendency estimation unit 102, particle risk for each mesh (partitioned data 1 and 2) indicating a probability that a defective chip may occur is estimated (S902-1 and S902-2). The estimation result is stored in the in-surface tendency data storage part 110-2 (S903).

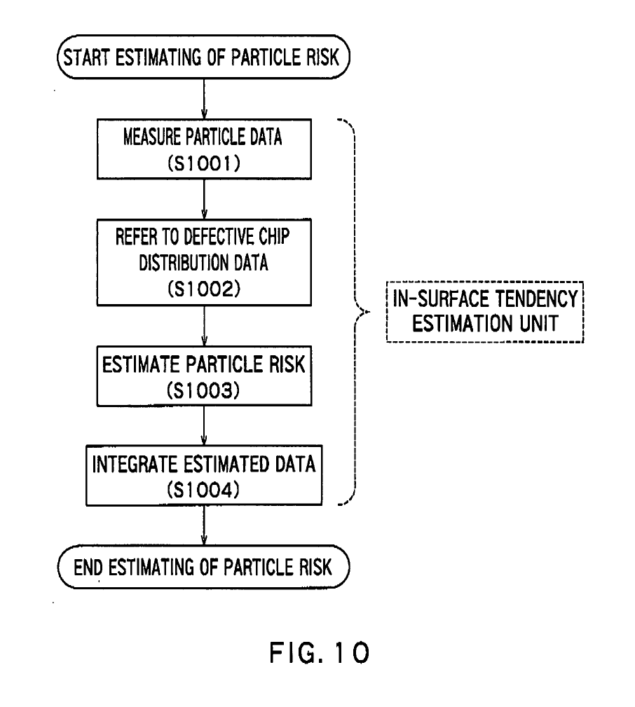

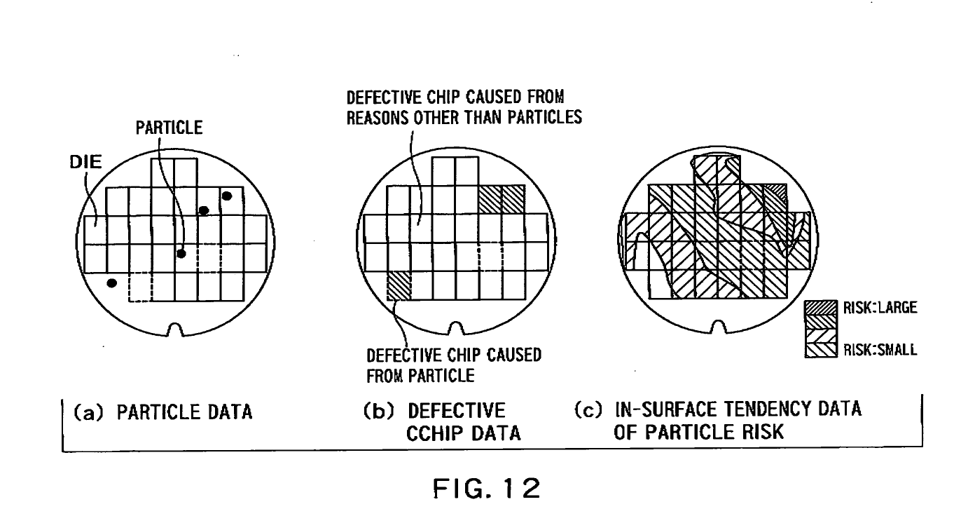

Now, an example of the particle risk estimation operations (S902-1 and S902-2) are described with reference to FIG. 10. Firstly, the in-surface tendency data estimation unit 102 measures a particle data (see FIG. 12A) on the surface of the wafer (S1001). Next, a previously-acquired defective chip distribution data (see FIG. 12B) is referred to (S1002). Next, the particle risk is estimated based on the measurement result which the referred result of the previously-acquired defective chip distribution data is reflected (S1003). Here, the estimation is performed on each mesh. Next, the estimation results of the meshes are integrated, so that the data (see FIG. 12C) for the entire surface of the wafer is acquired (S1004). In this manner, the particle risk estimation operations (S902-1 and S902-2) are ended.

Referring to FIG. 9, after the particle risk estimation operation, the acquired data for the entire surface of the wafer is stored in the in-surface tendency data storage part 110-3 (S903). Next, in the process condition setting unit 104, the process condition of the etching process (S206) is set (S904). Next, in the characteristic estimation unit 103, the electrical characteristic for the meshes are estimated (S905-1 and S905-2). Next, it is determined whether or the estimation result of the electrical characteristic is in the in-spec state (S906). If the electrical characteristic is determined to be in the out-of-spec state (No in S906), the process condition setting unit 104 repeats the setting of the process condition (S904) until the electrical characteristic is determined to be in the in-spec state. If the electrical characteristic is determined to be in the in-spec state (Yes in S906), the optimization is ended, and the set process condition is stored in the process condition storage part 110-1.

In the second embodiment, the determination S906 of the in-spec state may be performed in the same manner as the determination S706 of the first embodiment. In addition, the in-surface tendency data and the particle risk stored in the in-surface tendency data storage part 110-3 may be used. For example, in a case where the electrical characteristic stored in the characteristic data storage part 110-3 is reflected on the particle risk stored in the in-surface tendency data storage part 110-3, if the yield become more than a predetermined value, it may be determined to be in the in-spec state. In addition, in the determination S906 of the in-spec state, the best-yield process condition may be selected and set among a plurality of process conditions (for example, the process condition of the film forming process, the process condition of the CMP process, and the process condition of the etching process) and combinations of the process conditions.

According to the semiconductor device manufacturing method and system of the second embodiment, the process condition is set by using the in-surface tendency data for each predetermined region, so that the yield in terms of the entire surface of the wafer can be further increased in comparison with the first embodiment. In addition, according to the embodiment, the particle risk is considered, so that the yield can be further increased.

### Third Embodiment

Now, a third embodiment of a semiconductor device manufacturing method and system of capable of further Increasing a profit in terms of cost and performance in comparison with the second embodiment is described. In description of the third embodiment, the same constructions and operations as the first and second embodiments are omitted.

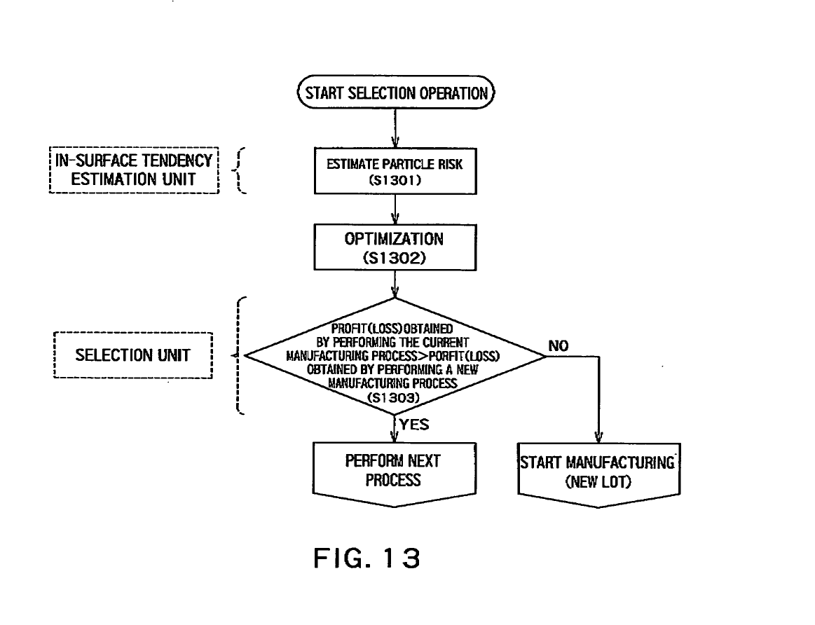

FIG. 13 shows an example of a selection operation performed the selection unit 106 according to the third embodiment. The selection operation is performed after the determination operation S906 shown in FIG. 9.

The selection unit 106 determines whether or not the performing of the uncompleted process (that is, the etching process S206 and the post-processing S208) is profitable by using the optimized process condition for the case of the in-spec state (Yes in S906) (S1303). If the performing of the uncompleted process is determined to be profitable (Yes in S1303), the next process, that is, the etching process S206 is performed. If the performing of the uncompleted process is determined not to be profitable (No in S1303), the etching process is not performed, but a new lot wafer manufacturing process is started (S201). Namely, the selection unit 106 selects the more profitable case between the case where the uncompleted process is performed (Yes in S1303) and the case where the new lot wafer is manufactured (No in S1303). In addition, when the new lot wafer is manufactured, the existing lot wafer where the performing of the CMP process is completed is discarded.

Now, an example of the determination S1303 of the selection unit 106 is described. The selection condition storage part 110-4 stores a sales data X associated with the yield obtained by the optimization, a sales data A associated with a standard yield, a cost data B1 associated with the performing of the manufacturing process shown in FIG. 2, and a cost data B2 associated with the performing of the uncompleted processes (the processes after the process S204 in the embodiment). The selection unit 106 performs the aforementioned determination process based on the following Equation 2.
X<A−B1 [Equation 2]

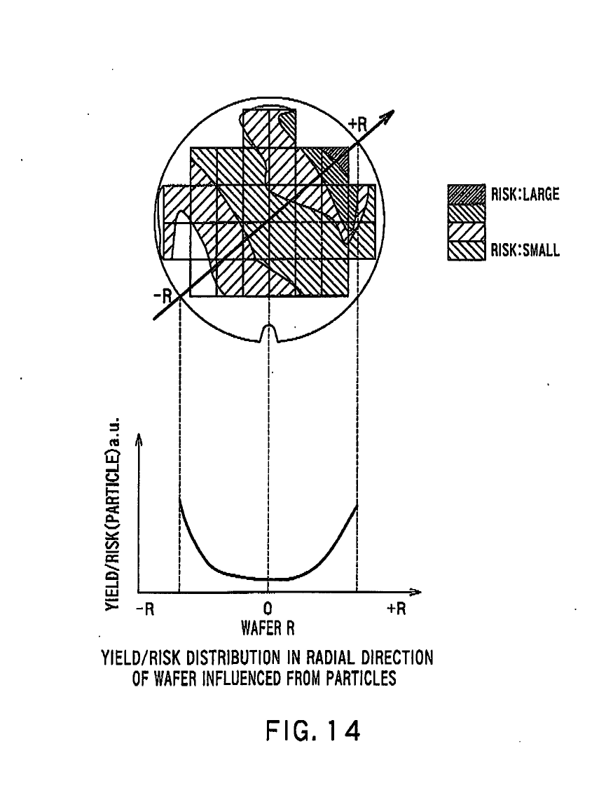

FIG. 14 shows a verification result for the influence of the particle risk (see FIG. 12C) to the yield. As shown in FIG. 14, it can be understood that the in-surface tendency and the yield risk greatly vary with the particle risk.

According to the semiconductor device manufacturing method and system of the third embodiment, if a wafer with the increased yield is determined not to be profitable, the etching process is not performed but a new lot wafer is manufactured, so that a loss caused from the manufacturing of an unnecessary lot wafer can be prevented. This can be easily seen from the verification result shown in FIG. 14.

The processes shown in FIGS. 7, 9, 10, and 13 may be performed by executing a predetermined program stored in the storage unit 110. The program may be stored in a computer-readable recording medium such as a flexible disc, a CD-ROM, and a MO disc.

What is claimed is;

1. A method for manufacturing a semiconductor device comprising:
measuring a finished state of a wafer in a completed process;
estimating an in-surface tendency of the wafer based on a result of the measuring;
estimating a surface characteristic of the wafer based on the estimated in-surface tendency;
setting a process condition of a uncompleted process based on the estimated surface characteristic; and
controlling the uncompleted process based on the set process condition.

2. The method for manufacturing a semiconductor device according to claim 1, wherein, in the setting of the process condition, if the estimated surface characteristic does not satisfy a predetermined specification, the process condition is modified to be set.

3. The method for manufacturing a semiconductor device according to claim 1, further comprising:
forming a insulating film on the wafer;
measuring a thickness of the formed insulating film in the measuring of the finished state;
estimating the in-surface tendency of the wafer based on the measured thickness in the estimating of the in-surface tendency;
setting a process condition of a chemical mechanical polishing (CMP) process, an etching process, or a post-processing based on the estimated surface characteristic in the setting of the process condition; and
controlling the CMP process, the etching process, or the post-processing based on the set process condition in the controlling of the uncompleted process.

4. The method for manufacturing a semiconductor device according to claim 1, further comprising:
polishing the wafer on which a insulating film is formed, by performing a CMP;
measuring a thickness of the insulating film formed on the polished wafer in the measuring of the finished state;
estimating the in-surface tendency of the wafer based on the measured thickness in the estimating of the in-surface tendency;
setting a process condition of a etching process or a post-processing based on the estimated surface characteristic in the setting of the process condition; and
controlling the etching process or the post-processing based on the set process condition in the controlling of the uncompleted process.

5. The method for manufacturing a semiconductor device according to claim 1, further comprising:
selectively etching a silicon oxide film formed on the wafer;
measuring a remaining thickness of the etched silicon oxide film in the measuring of the finished state;
estimating the in-surface tendency of the wafer based on the measured remaining thickness in the estimating of the in-surface tendency;
setting a process condition of a post-processing based on the estimated surface characteristic in the setting of the process condition; and
controlling the post-processing based on the set process condition in the controlling of the uncompleted process.

6. The method for manufacturing a semiconductor device according to claim 1, further comprising:
acquiring a partitioned data from predetermined partitioned regions of the wafer and estimating states of a completed process of the partitioned regions corresponding to partitioned data in the estimating of the in-surface tendency;
estimating a characteristic of the completed process of the partitioned regions based on the estimated state of the completed process in the estimating of the surface characteristic; and
integrating the estimated characteristic of the completed processes and setting a process condition of a uncompleted process based on the a result of the integration of the estimated characteristic in the setting of the process condition.

7. The method for manufacturing a semiconductor device according to claim 6, wherein, in the setting of the process condition, if the estimated surface characteristic does not satisfy a predetermined specification, the process condition is modified to be set.

8. The method for manufacturing a semiconductor device according to claim 6, further comprising;
measuring particles on the surface of the wafer in the completed process and estimating particle risk based on the measured particles in the estimating of the in-surface tendency; and
controlling the uncompleted process based on the estimated particle risk and the set process condition in the controlling of the uncompleted process.

9. The method for manufacturing a semiconductor device according to claim 8, further comprising:
selecting performing of the uncompleted process or starting of a new lot wafer manufacturing process based on the estimated particle risk on the surface of the wafer; and
controlling the uncompleted process based on a result of the selecting in the controlling of the uncompleted process.

10. The method for manufacturing a semiconductor device according to claim 9, further comprising: in the selecting of the starting of the manufacturing process,
comparing a profit to be obtained from the performing of the uncompleted process with a profit to be obtained from the performing the new lot wafer manufacturing process based on the estimated particle risk on the surface of the wafer; and
selecting the performing of the uncompleted process or the starting of the new lot wafer manufacturing process based on a result of the comparing.

11. A system for manufacturing a semiconductor device comprising:
an in-surface tendency estimation unit which measures a finished state of a wafer in a completed process and estimates an in-surface tendency of the wafer based on a result of the measuring;
a characteristic estimation unit which estimates a surface characteristic of the wafer based on the estimated in-surface tendency;
a process condition setting unit which sets a process condition of a uncompleted process based on the estimated surface characteristic; and
a controller which controls the uncompleted process based on the set process condition.

12. The system for manufacturing a semiconductor device according to claim 11, wherein, if the estimated surface characteristic does not satisfy a predetermined specification, the process condition setting unit modifies the process condition to be set.

13. The system for manufacturing a semiconductor device according to claim 11, further comprising:
a film forming process unit which performs a process of forming a insulating film on the wafer;
a CMP process unit which performs a CMP process to polish the wafer on which the insulating film is formed by the film forming process unit;
an etching process unit which selectively etches a silicon oxide film formed on the wafer polished by the CMP process unit; and
a post-processing unit which performs a post-processing on the wafer selectively etched by the etching process unit,
wherein the in-surface tendency estimation unit measures a thickness of the insulating film formed by the film forming process unit and estimates the in-surface tendency of the wafer based on the measured thickness,
wherein the process condition setting unit sets a process condition of the CMP process unit, the etching process unit, or the post-processing unit based on the estimated surface characteristic, and
wherein the controller controls the CMP process unit, the etching process unit, or the post-processing unit based on the set process condition.

14. The system for manufacturing a semiconductor device according to claim 11, further comprising:
a film forming process unit which performs a process of forming a insulating film on the wafer;
a CMP process unit which performs a CMP process to polish the wafer on which the insulating film is formed by the film forming process unit;
an etching process unit which selectively etches a silicon oxide film formed on the wafer polished by the CMP process unit; and
a post-processing unit which performs a post-processing on the wafer selectively etched by the etching process unit,
wherein the in-surface tendency estimation unit measures a thickness of the insulating film formed on the wafer polished by the CMP process unit and estimates the in-surface tendency of the wafer based on the measured thickness,
wherein the process condition setting unit sets a process condition of the etching process unit or the post-processing unit based on the estimated surface characteristic, and
wherein the controller controls the etching process unit or the post-processing unit based on the set process condition.

15. The system for manufacturing a semiconductor device according to claim 11, further comprising:
a film forming process unit which performs a process of forming a insulating film on the wafer;
a CMP process unit which performs a CMP process to polish the wafer on which the insulating film is formed by the film forming process unit;
an etching process unit which selectively etches a silicon oxide film formed on the wafer polished by the CMP process unit; and
a post-processing unit which performs a post-processing on the wafer selectively etched by the etching process unit,
wherein the in-surface tendency estimation unit measures a remaining thickness of the silicon oxide film etched by the etching process unit and estimates the in-surface tendency of the wafer based on the measured remaining thickness,
wherein the process condition setting unit sets a process condition of the post-processing unit based on the estimated surface characteristic, and
wherein the controller controls the post-processing unit based on the set process condition.

16. The system for manufacturing a semiconductor device according to claim 11, further comprising:
a partitioned data acquisition unit which acquires partitioned data from predetermined partitioned regions of the wafer,
wherein the in-surface tendency estimation unit estimates states of a completed process of the partitioned regions corresponding to partitioned data acquired by the partitioned data acquisition unit,
wherein the surface characteristic estimation unit estimates characteristic of the completed process of the partitioned regions based on the state of the completed process estimated by the in-surface tendency estimation unit, and
wherein the process condition setting unit integrates the characteristic of the completed processes estimated by the surface characteristic estimation unit and sets a process condition of a uncompleted process based on the a result of the integration of the estimated characteristic.

17. The system for manufacturing a semiconductor device according to claim 16, wherein, if the estimated surface characteristic does not satisfy a predetermined specification, the process condition setting unit modifies the process condition to be set.

18. The system for manufacturing a semiconductor device according to claim 16,
wherein the in-surface tendency estimation unit measures particles on the surface of the wafer in the completed process and estimates particle risk based on the measured particles, and
wherein the controller controls the uncompleted process based on the particle risk estimated by the in-surface tendency estimation unit and the process condition set by the process condition setting unit.

19. The system for manufacturing a semiconductor device according to claim 18,
further comprising a selection unit which selects performing of the uncompleted process or starting of a new lot wafer manufacturing process based on the particle risk on the surface of the wafer estimated by the in-surface tendency estimation unit,
wherein the controller controls the uncompleted process based on a result of the selecting of the selection unit.

20. The system for manufacturing a semiconductor device according to claim 19,
wherein the selection unit compares a profit to be obtained from the performing of the uncompleted process with a profit to be obtained from the performing the new lot wafer manufacturing process based on the particle risk estimated by the in-surface tendency estimation unit and selects the performing of the uncompleted process or the starting of the new lot wafer manufacturing process based on a result of the comparing.
